(19) United States
(12) Patent Application Publication
(10) Pub. No.: US 2023/0317452 A1
(43) Pub. Date: Oct. 5, 2023

(54) HARD MASK STRUCTURE

(71) Applicant: NANYA TECHNOLOGY CORPORATION, New Taipei City (TW)

(72) Inventors: Sheng-Fu HUANG, New Taipei City (TW); Kuan Hua CHEN, Yunlin County (TW)

(21) Appl. No.: 17/657,364

(22) Filed: Mar. 31, 2022

(51) Int. Cl. H01L 21/027

(52) U.S. Cl. CPC H01L 21/0273; H01L 21/0272

(57) ABSTRACT

A hard mask structure includes a tungsten-based conductive layer, a carbon-based hard mask layer and a nitride layer. The carbon-based hard mask layer is formed over the Tungsten-based conductive layer. The nitride layer is formed between the tungsten-based conductive layer and the carbon-based hard mask layer to enhance adhesion therebetween.

### BACKGROUND

### Field of Disclosure

The present disclosure relates to a hard mask structure used in a semiconductor manufacturing processing.

### Description of Related Art

Due to the high cost of silicon wafer and the need to create ever smaller memory devices, monolithic 3-D memory devices have become increasingly popular. Such devices can include multiple levels of interconnected memory cells. However, various difficulties have been encountered in etching the metal layers. For example, conventional hard mask techniques may induce film peeling issues. As a result, such hard mask techniques can exacerbate line etch roughness, obscure underlying alignment and overlay marks, and be difficult to integrate or remove. As 3-D monolithic integrated circuits push minimum feature sizes and etch and fill aspect ratios to the limit, presenting very demanding requirements, conventional hard mask techniques have been found to be inadequate.

### SUMMARY

The present disclosure provides hard mask structures to deal with the needs of the prior art problems.

In one or more embodiments, a hard mask structure includes a tungsten-based conductive layer, a carbon-based hard mask layer and a nitride layer. The carbon-based hard mask layer is formed over the Tungsten-based conductive layer. The nitride layer is formed between the tungsten-based conductive layer and the carbon-based hard mask layer.

In one or more embodiments, a hard mask structure includes a tungsten-based conductive layer, a first hard mask layer, a second hard mask layer and a nitride layer. The first hard mask layer is formed over the tungsten-based conductive layer, wherein the first hard mask layer is a carbon-based hard mask layer. The second hard mask layer is formed over the first hard mask layer. The nitride layer is formed between the tungsten-based conductive layer and the first hard mask layer.

In one or more embodiments, the tungsten-based conductive layer includes a tungsten alloy.

In one or more embodiments, the tungsten-based conductive layer includes a tungsten silicide.

In one or more embodiments, the carbon-based hard mask layer includes diamond-like carbon.

In one or more embodiments, the carbon-based hard mask layer includes amorphous carbon.

In one or more embodiments, the carbon-based hard mask layer includes graphite.

In one or more embodiments, the nitride layer has two opposite surfaces in physical contact with the tungsten-based conductive layer and the first hard mask layer respectively.

In one or more embodiments, the nitride layer includes silicon nitride.

In one or more embodiments, the nitride layer has a thickness ranging from 3 nanometers to 15 nanometers.

In one or more embodiments, the nitride layer is an atomic layer deposition layer.

In one or more embodiments, the second hard mask layer is a non-carbon-based hard mask layer.

In sum, the hard mask structure disclosed herein introduces a nitride layer between the carbon-based hard mask layer and the tungsten-based conductive layer. The nitride layer has two opposite surfaces in physical contact with the tungsten-based conductive layer and the carbon-based hard mask layer respectively to balance the stress and enhance the adhesion therebetween. The nitride layer is also used to protect the tungsten-based conductive layer from being oxidized when the carbon-based hard mask layer is removed by a plasma ashing process.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a cross sectional view of a hard mask structure according to an embodiment of the present disclosure; and

FIG. 2 illustrates a cross sectional view of a hard mask structure according to another embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

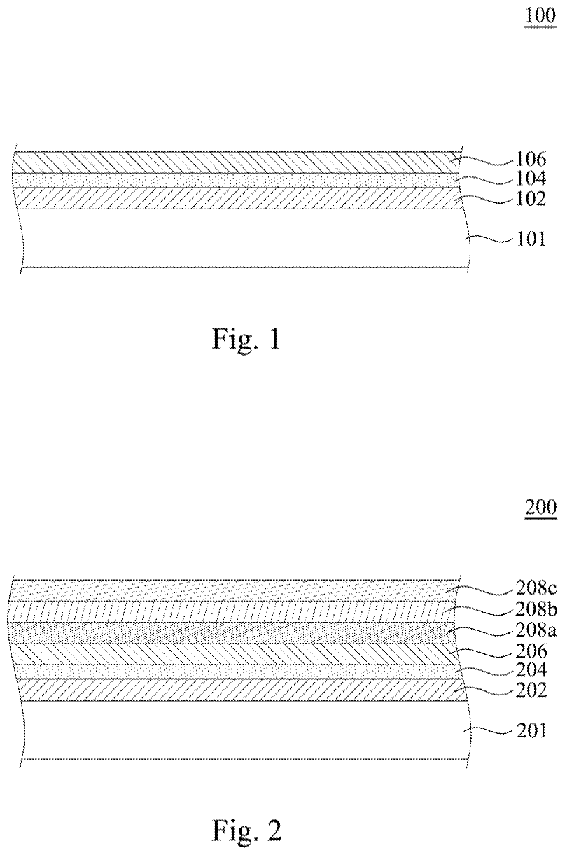

Reference is made to FIG. 1, which illustrates a cross sectional view of a hard mask structure according to an embodiment of the present disclosure. A hard mask structure 100 is formed in contact with a substrate or a processing film layer 101. In some embodiments of the present disclosure, the substrate may be a semiconductor substrate, such as a bulk semiconductor, a semiconductor-on-insulator (SOI) substrate, or the like, which may be doped (e.g., with a p-type or an n-type dopant) or undoped. The substrate may be an integrated circuit die, such as a logic die, a memory die, an ASIC die, or the like. The substrate may be a complementary metal oxide semiconductor (CMOS) die and may be referred to as a CMOS under array (CUA). The substrate may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate.

In some embodiments of the present disclosure, the hard mask structure 100 may include a tungsten-based conductive layer 102, a carbon-based hard mask layer 106 and a nitride layer 104 presented between the tungsten-based conductive layer 102 and the carbon-based hard mask layer 106. In a conventional hard mask structure, a carbon-based hard mask layer may be formed in contact with a tungsten-based conductive layer, and the carbon-based hard mask layer may be peeling due to a poor adhesion between the carbon-based hard mask layer and the tungsten-based conductive layer. The nitride layer 104 is formed between the tungsten-based conductive layer 102 and the carbon-based hard mask layer 106 to enhance the adhesion therebetween. That is, the nitride layer 104 has two opposite surfaces in physical contact with the tungsten-based conductive layer 102 and the carbon-based hard mask layer 106 respectively to enhance the adhesion therebetween. In some embodiments of the present disclosure, the nitride layer 104 may be a silicon nitride (Si₃N₄) layer. In some embodiments of the present disclosure, the nitride layer 104 may have a thickness ranging from about 3 nanometers to about 15 nanometers to achieve its effective performance, i.e., enhance adhesion between two layers. When a thickness of the nitride layer 104 is greater than about 15 nanometers, a combination of the carbon-based hard mask layer 106 and the nitride layer 104 is too thick to achieve narrower pattern on the tungsten-based conductive layer 102. When a thickness of the nitride layer 104 is smaller than about 3 nanometers, the nitride layer 104 is too thin to balance the stress between the tungsten-based conductive layer 102 and the carbon-based hard mask layer 106 such that the adhesion between these two layers may not be improved. In some embodiments of the present disclosure, the nitride layer 104 is formed by an atomic layer deposition (ALD) process to achieve desired film quality to balance the stress between the tungsten-based conductive layer 102 and the carbon-based hard mask layer 106. With the nitride layer 104 improving adhesion between the tungsten-based conductive layer 102 and the carbon-based hard mask layer 106, the peeling issue would be improved and the defects due to the peeling issue can be effectively reduced.

In some other embodiments of the present disclosure, the nitride layer 104 may include at least one of the materials: Aluminum Nitride (AlN), Barium Nitride (Ba₃N₂), Boron Nitride (BN), Calcium Nitride (Ca₃N₂), Cerium Nitride (CeN), Europium Nitride (EuN), Galium Nitride (GaN), Indium Nitride (InN), Lanthanum Nitride (LaN), Lithium Nitride (Li₃N), Magnesium Nitride (Mg₃N₂), Niobium Nitride (NbN), Strontium Nitride (Sr₃N₂), Tantalum Nitride (TaN), Vanadium Nitride (VN), Zinc Nitride(Zn₃N₂), Zirconium Nitride (ZrN), and etc.

After the tungsten-based conductive layer 102 is etched to a desired pattern, the carbon-based hard mask layer 106 may be removed by a plasma ashing process, which requires introducing oxygen (02) to into a vacuum chamber. Oxygen then ionizes and becomes oxygen plasma which can be used to oxidize the carbon-based hard mask layer 106. The nitride layer 104 over the tungsten-based conductive layer 102 is not removed by the plasma ashing process, and used to protect the tungsten-based conductive layer 102 from being oxidized.

The tungsten-based conductive layer 102 can be used as metal interconnecting piece between component devices. The tungsten-based conductive layer can be deposited using electroplating or electroless plating. In some embodiments of the present disclosure, the tungsten-based conductive layer 102 may include a tungsten alloy. In some embodiments of the present disclosure, the tungsten alloy may include tungsten-nickel-copper alloys. In some embodiments of the present disclosure, the tungsten alloy may include tungsten-nickel-iron alloys. In some embodiments of the present disclosure, the tungsten-based conductive layer 102 may include a tungsten silicide layer. In some embodiments of the present disclosure, a conductive cobalt-tungsten alloy includes tungsten of 15 to 45 atomic percent, cobalt of 50 to 80 atomic percent, and boron of 1 to 5 atomic percent. In some embodiments of the present disclosure, a conductive cobalt-tungsten alloy includes the tungsten of 20 to 40 atomic percent, cobalt of 55 to 75 atomic percent and boron of 1 to 5 atomic percent. In some embodiments of the present disclosure, a conductive cobalt-tungsten alloy includes tungsten of 25 to 35 atomic percent, cobalt of 60 to 70 atomic percent and boron of 1 to 5 atomic percent. In some embodiments of the present disclosure, a conductive nickel-tungsten alloy includes tungsten of 15 to 45 atomic percent, nickel of 50 to 80 atomic percent and boron of 1 to 5 atomic percent. In some embodiments of the present disclosure, a conductive nickel-tungsten alloy includes tungsten of 20 to 40 atomic percent, nickel of 55 to 75 atomic percent and boron of 1 to 5 atomic percent. In some embodiments of the present disclosure, a conductive nickel-tungsten alloy includes tungsten of 25 to 35 atomic percent, and nickel of 60 to 70 atomic percent and boron of 1 to 5 atomic percent.

In some embodiments of the present disclosure, the carbon-based hard mask layer 106 may include diamond-like carbon materials. In some embodiments of the present disclosure, the carbon-based hard mask layer 106 may include amorphous carbon materials. In some embodiments of the present disclosure, the carbon-based hard mask layer 106 may include graphite materials.

In some embodiments of the present disclosure, the carbon-based hard mask layer 106 may be formed, for example, by chemical vapor deposition (CVD), physical vapor deposition (PVD), or atomic layer deposition (ALD). To increase the deposition effect, the hard mask layer 106 may use a plasma. For example, the hard mask layer 106 may be formed by, e.g., plasma enhanced CVD (PECVD) or plasma enhanced ALD (PEALD).

Reference is made to FIG. 2, which illustrates a cross sectional view of a hard mask structure according to another embodiment of the present disclosure. A hard mask structure 200 is formed in contact with a substrate or a processing film layer 201. The hard mask structure 200 is different from the hard mask structure 100 in that the hard mask structure 200 include more hard mask layers (208a, 208b, 208c) formed over the carbon-based hard mask layer 206. In some embodiments of the present disclosure, the substrate may be a semiconductor substrate, such as a bulk semiconductor, a semiconductor-on-insulator (SOI) substrate, or the like, which may be doped (e.g., with a p-type or an n-type dopant) or undoped. The substrate may be an integrated circuit die, such as a logic die, a memory die, an ASIC die, or the like. The substrate may be a complementary metal oxide semiconductor (CMOS) die and may be referred to as a CMOS under array (CUA). The substrate may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate.

In some embodiments of the present disclosure, the hard mask structure 200 may be used in double patterning lithography or multiple-patterning lithography, i.e., Litho-etch-litho-etch (LELE) patterning lithography, which needs multiple hard mask layers. Litho-etch-litho-etch is a form of double patterning. Litho-etch-litho-etch is also called pitch splitting. Litho-etch-litho-etch may be used for extending the capabilities of photolithographic techniques beyond the minimum pitch capabilities of existing lithographic equipment. In LELE, two separate lithography and etch steps are performed to define a single layer, thereby doubling the pattern density. Initially, this technique separates the layouts that cannot be printed with a single exposure, forming two lower-density masks. Then, it uses two separate exposure processes and multiple hard mask layers are needed.

In some embodiments of the present disclosure, either one of the hard mask layers (208a, 208b, 208c) may be a non-carbon-based hard mask layer. In some embodiments of the present disclosure, any two of the hard mask layers (208a, 208b, 208c) may be non-carbon-based hard mask layers. In some embodiments of the present disclosure, the hard mask layers (208a, 208b, 208c) are all non-carbon-based hard mask layers. In some embodiments of the present disclosure, one or more of the hard mask layers (208a, 208b, 208c) may be formed, for example, by chemical vapor deposition (CVD), physical vapor deposition (PVD), or atomic layer deposition (ALD). To increase the deposition effect, the hard mask layers (208a, 208b, 208c) may be formed by using a plasma. For example, one or more of the hard mask layers (208a, 208b, 208c) may be formed by, e.g., plasma enhanced CVD (PECVD) or plasma enhanced ALD (PEALD).

In some embodiments of the present disclosure, the hard mask structure 200 may include a tungsten-based conductive layer 202, a carbon-based hard mask layer 206 and a nitride layer 204 presented between the tungsten-based conductive layer 202 and the carbon-based hard mask layer 206. In a conventional hard mask structure, a carbon-based hard mask layer may be formed in contact with a tungsten-based conductive layer, and the carbon-based hard mask layer may be peeling due to a poor adhesion between the carbon-based hard mask layer and the tungsten-based conductive layer, and more defects would be found because of the peeling issue. The nitride layer 204 is formed between the tungsten-based conductive layer 202 and the carbon-based hard mask layer 206 to enhance the adhesion therebetween. That is, the nitride layer 204 has two opposite surfaces in physical contact with the tungsten-based conductive layer 202 and the carbon-based hard mask layer 206 respectively to enhance the adhesion therebetween. In some embodiments of the present disclosure, the nitride layer 204 may be a silicon nitride (Si₃N₄) layer. In some embodiments of the present disclosure, the nitride layer 204 may have a thickness ranging from about 3 nanometers to about 15 nanometers to achieve its effective performance, i.e., enhance adhesion between two layers. When a thickness of the nitride layer 204 is greater than about 15 nanometers, a combination of the carbon-based hard mask layer 206 and the nitride layer 204 is too thick to achieve narrow pattern on the tungsten-based conductive layer 202. When a thickness of the nitride layer 204 is smaller than about 3 nanometers, the nitride layer 204 is too thin to balance the stress between the tungsten-based conductive layer 202 and the carbon-based hard mask layer 206 such that the adhesion between these two layers may not be improved. In some embodiments of the present disclosure, the nitride layer 204 is formed by an atomic layer deposition (ALD) process to achieve desired film quality to balance the stress between the tungsten-based conductive layer 202 and the carbon-based hard mask layer 206. With the nitride layer 204 improving adhesion between the tungsten-based conductive layer 202 and the carbon-based hard mask layer 206, the peeling issue would be improved and the defects due to the peeling issue can be effectively reduced.

In some other embodiments of the present disclosure, the nitride layer 204 may include at least one of the materials: Aluminum Nitride (AlN), Barium Nitride (Ba₃N₂), Boron Nitride (BN), Calcium Nitride (Ca₃N₂), Cerium Nitride (CeN), Europium Nitride (EuN), Galium Nitride (GaN), Indium Nitride (InN), Lanthanum Nitride (LaN), Lithium Nitride (Li₃N), Magnesium Nitride (Mg₃N₂), Niobium Nitride (NbN), Strontium Nitride (Sr₃N₂), Tantalum Nitride (TaN), Vanadium Nitride (VN), Zinc Nitride(Zn₃N₂), Zirconium Nitride (ZrN), and etc.

After the tungsten-based conductive layer 202 is etched to a desired pattern, the carbon-based hard mask layer 206 may be removed by a plasma ashing process, which requires introducing oxygen (02) to into a vacuum chamber. Oxygen then ionizes and becomes oxygen plasma which can be used to oxidize the carbon-based hard mask layer 206. The nitride layer 204 over the tungsten-based conductive layer 202 is not removed by the plasma ashing process, and used to protect the tungsten-based conductive layer 202 from being oxidized.

The tungsten-based conductive layer 202 can be used as metal interconnecting piece between component devices. The tungsten-based conductive layer can be deposited using electroplating or electroless plating. In some embodiments of the present disclosure, the tungsten-based conductive layer 202 may include a tungsten alloy. In some embodiments of the present disclosure, the tungsten alloy may include tungsten-nickel-copper alloys. In some embodiments of the present disclosure, the tungsten alloy may include tungsten-nickel-iron alloys. In some embodiments of the present disclosure, the tungsten-based conductive layer 202 may include a tungsten silicide layer. In some embodiments of the present disclosure, a conductive cobalt-tungsten alloy includes tungsten of 15 to 45 atomic percent, cobalt of 50 to 80 atomic percent, and boron of 1 to 5 atomic percent. In some embodiments of the present disclosure, a conductive cobalt-tungsten alloy includes the tungsten of 20 to 40 atomic percent, cobalt of 55 to 75 atomic percent and boron of 1 to 5 atomic percent. In some embodiments of the present disclosure, a conductive cobalt-tungsten alloy includes tungsten of 25 to 35 atomic percent, cobalt of 60 to 70 atomic percent and boron of 1 to 5 atomic percent. In some embodiments of the present disclosure, a conductive nickel-tungsten alloy includes tungsten of 15 to 45 atomic percent, nickel of 50 to 80 atomic percent and boron of 1 to 5 atomic percent. In some embodiments of the present disclosure, a conductive nickel-tungsten alloy includes tungsten of 20 to 40 atomic percent, nickel of 55 to 75 atomic percent and boron of 1 to 5 atomic percent. In some embodiments of the present disclosure, a conductive nickel-tungsten alloy includes tungsten of 25 to 35 atomic percent, and nickel of 60 to 70 atomic percent and boron of 1 to 5 atomic percent.

In some embodiments of the present disclosure, the carbon-based hard mask layer 206 may include diamond-like carbon materials. In some embodiments of the present disclosure, the carbon-based hard mask layer 206 may include amorphous carbon materials. In some embodiments of the present disclosure, the carbon-based hard mask layer 206 may include graphite materials.

In some embodiments of the present disclosure, the carbon-based hard mask layer 206 may be formed, for example, by chemical vapor deposition (CVD), physical vapor deposition (PVD), or atomic layer deposition (ALD). To increase the deposition effect, the hard mask layer 206 may be formed by using a plasma. For example, the hard mask layer 206 may be formed by, e.g., plasma enhanced CVD (PECVD) or plasma enhanced ALD (PEALD).

In sum, the hard mask structure disclosed herein introduces a nitride layer between the carbon-based hard mask layer and the tungsten-based conductive layer. The nitride layer has two opposite surfaces in physical contact with the tungsten-based conductive layer and the carbon-based hard mask layer respectively to balance the stress and enhance the adhesion therebetween. The nitride layer is also used to protect the tungsten-based conductive layer from being oxidized when the carbon-based hard mask layer is removed by a plasma ashing process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A hard mask structure comprising:
a tungsten-based conductive layer;
a carbon-based hard mask layer disposed over the tungsten-based conductive layer; and
a nitride layer disposed between the tungsten-based conductive layer and the carbon-based hard mask layer.

2. The hard mask structure of claim 1, wherein the tungsten-based conductive layer comprises a tungsten alloy.

3. The hard mask structure of claim 1, wherein the tungsten-based conductive layer comprises tungsten silicide.

4. The hard mask structure of claim 1, wherein the carbon-based hard mask layer comprises diamond-like carbon.

5. The hard mask structure of claim 1, wherein the carbon-based hard mask layer comprises amorphous carbon.

6. The hard mask structure of claim 1, wherein the carbon-based hard mask layer comprises graphite.

7. The hard mask structure of claim 1, wherein the nitride layer comprises silicon nitride, and the nitride layer has two opposite surfaces in physical contact with the tungsten-based conductive layer and the carbon-based hard mask layer respectively.

8. The hard mask structure of claim 1, wherein the nitride layer has a thickness ranging from 3 nanometers to 15 nanometers.

9. The hard mask structure of claim 1, wherein the nitride layer is an atomic layer deposition layer.

10. A hard mask structure comprising:
a tungsten-based conductive layer;
a first hard mask layer disposed over the tungsten-based conductive layer, wherein the first hard mask layer is a carbon-based hard mask layer;
a second hard mask layer disposed over the first hard mask layer; and
a nitride layer disposed between the tungsten-based conductive layer and the first hard mask layer.

11. The hard mask structure of claim 10, wherein the nitride layer has two opposite surfaces in physical contact with the tungsten-based conductive layer and the first hard mask layer respectively.

12. The hard mask structure of claim 10, wherein the nitride layer comprises silicon nitride.

13. The hard mask structure of claim 10, wherein the tungsten-based conductive layer comprises a tungsten alloy.

14. The hard mask structure of claim 10, wherein the tungsten-based conductive layer comprises tungsten silicide.

15. The hard mask structure of claim 10, wherein the carbon-based hard mask layer comprises diamond-like carbon.

16. The hard mask structure of claim 10, wherein the carbon-based hard mask layer comprises amorphous carbon.

17. The hard mask structure of claim 10, wherein the carbon-based hard mask layer comprises graphite.

18. The hard mask structure of claim 10, wherein the second hard mask layer is a non-carbon-based hard mask layer.

19. The hard mask structure of claim 10, wherein the nitride layer has a thickness ranging from 3 nanometers to 15 nanometers.

20. The hard mask structure of claim 10, wherein the nitride layer is an atomic layer deposition layer.
